(19) United States
(12) Patent Application Publication
(10) Pub. No.: US 2013/0136861 A1
(43) Pub. Date: May 30, 2013

(54) METHOD FOR COATING AT LEAST THE INNER FACE OF A PISTON RING AND PISTON RING

(71) Applicants: Dirk Barenreuter, Odenthal (DE); Marcus Kennedy, Dusseldorf (DE); Markus Kellner, Leverkusen (DE); Ralf Lammers, Wermelskirchen (DE)

(72) Inventors: Dirk Barenreuter, Odenthal (DE); Marcus Kennedy, Dusseldorf (DE); Markus Kellner, Leverkusen (DE); Ralf Lammers, Wermelskirchen (DE)

(21) Appl. No.: 13/583,715

(22) PCT Filed: Feb. 17, 2011
(86) PCT No.: PCT/EP2011/052342

§ 371 Date: Nov. 20, 2012

(30) Foreign Application Priority Data
Mar. 9, 2010 (DE) 10 2010 002 687.5

(51) Int. Cl. C23C 16/02

(52) U.S. Cl. CPC C23C 16/0272
USPC 427/249.18; 427/249.19

(57) ABSTRACT

In a method for coating at least part of the inner face of a piston ring, said ring preferably consisting of cast iron or steel, a PVD and/or DLC coating is applied by means of at least one of the following methods: PA-CVD, glow discharge and/or HIPIMS. A piston ring has a coating that is formed at least on part of the inner face of said ring, said coating being a PVD and/or DLC coating that preferably has been applied by means of PA-CVD, glow discharge and/or HIPIMS.

### FIELD OF THE INVENTION

The invention relates to a method for coating at least the inner face of a piston ring, and to a piston ring.

The piston ring to be coated according to the invention is typically provided as a component of a two-part oil scraper ring in a piston of an internal combustion engine. The actual piston ring, which is in sliding contact with a cylinder or a cylinder liner, is pressed against the cylinder wall by a helical compression spring located on the inside. Accordingly, at the inner face of the piston ring, relative movements occur between the piston ring and the helical compression spring due to dynamic stress during operation of the engine. This movement can lead to so-called secondary wear, which can manifest itself on the piston ring in the form of channels in the groove and on the spring in the form of abraded material. The spring can catch in the channels in the groove, which impairs the scraping action of the piston ring. Furthermore, there can be a reduction in the tangential force required to perform the function.

### PRIOR ART

DE 196 51 112 A1 relates to an oil scraper ring on an engine piston rod, which oil scraper ring is provided fully with a coating.

JP2006349019 (A) discloses a piston ring having an amorphous hard carbon coating.

### DESCRIPTION OF THE INVENTION

The object underlying the invention is to provide a method for coating a piston ring, and a coated piston ring, with which the friction and/or wear behaviour of at least one component of a two-part oil scraper ring is improved.

The object is achieved on the one hand by the method described in claim 1.

Consequently, a PVD and/or DLC layer is applied to a piston ring, preferably made of cast iron or steel, by means of at least one of the processes PA-CVD (plasma-assisted chemical vapour deposition), glow discharge or high ionisation processes, such as, for example, HIPIMS. It has been found for the described processes that, in a surprising and novel manner, the coating of the inner face of a piston ring can thereby be formed in good quality and in a manner that is feasible in terms of process technology. Accordingly, it is possible for the first time to provide the inner face of a piston ring with effective wear protection against the helical compression or coil spring. It should be mentioned that the piston ring can have on its inner side a groove for receiving the coil spring. In this context, “coating at least on the inner side” is understood as meaning that the piston ring is coated on its cylindrical inner face and preferably at least in those regions, for example in the region of a coil spring groove, that are in contact with the coil spring. However, further surfaces, such as the flanks and/or the running surface, can be provided with the coating described herein.

It has been found that the described layers have very low coefficients of friction. Consequently, low wear on the coil spring is additionally advantageously to be expected. Finally, the described layers are comparatively extremely chemically resistant, so that deposits are prevented and a further improvement in the mobility of the oil ring system as a whole is advantageously achieved. The DLC layer can be in the form of a hydrogen-free layer, in particular in the form a-C or ta-C. A hydrogen-containing but metal-free layer, for example in the form a-C:H or ta-C:H, is further conceivable.

Preferred further developments are described in the further claims.

For the layer thickness which advantageously fulfils the demands that are made, a range of from 0.5 μm to 10 μm has been found.

For the PVD layer, particularly good results have been found in initial tests where that layer is formed of nitrides and/or carbides of at least one of the metals chromium, titanium, aluminium and tungsten. The deposition of the nitrides and carbides can take place alternately or simultaneously.

Particularly good results have been achieved for PVD layers having a hardness of from 800 to 4000 HV0.1.

For the amorphous carbon or DLC layer, preference is given to a structure which has at least one of the following layers and facing the base material of the piston ring first has an adhesive layer of chromium and/or titanium having a layer thickness of 1.0 μm or less. This is followed by a metal- or semiconductor-containing intermediate layer, that is to say a-C:H:Me, with tungsten, titanium or chromium as the metal, or a-C:H:X with X=silicon and/or germanium as semiconductor and/or one or more of the constituents fluorine, boron, oxygen and nitrogen. The thickness of this intermediate layer is preferably from 0.1 μm to 5 μm. The described structure is completed by a metal-free top layer of the type a-C:H having a thickness of preferably from 0.1 μm to 5 μm.

Particularly good properties have been found for a metal-containing DLC intermediate layer that contains nanocrystalline metal or metal carbide depositions, such as, for example, WC, CrC, SiC, GeC or TiC.

For the DLC layer, advantageous properties have been found with a hardness of from 2000 to 5000 HV0.002.

In addition to the processes described above, sputtering and in particular hollow cathode glow discharge processes can also be used for the DLC layer.

The object mentioned above is further achieved by the piston ring described in claim 8. Preferred embodiments thereof are obtained by applying the preferred method features described above.

It should further be mentioned that it is also possible to apply to the piston ring described herein, which is coated at least on its inner face, an embodiment of the coating that is described by the applicant in the application filed on the same day and having the title “Sliding element, in particular a piston ring, and method for coating a sliding element”. Furthermore, the piston ring described herein, which is coated in particular on the inner face, can advantageously be combined with the helical compression spring described in the application filed on the same day and having the title “Helical compression spring for an oil scraper ring of a piston in an internal combustion engine and method for coating a helical compression spring” in one of the embodiments described therein.

1. Method for coating at least the inner face of a piston ring at least partially, which piston ring is preferably made of cast iron or steel, in which a PVD and/or DLC layer is applied by means of at least one of the processes PA-CVD, glow discharge and/or HIPIMS.

2. Method according to claim 1,
characterised in that the coating is applied with an overall thickness of from 0.1 μm to 10 μm.

3. Method according to claim 1 or 2,
characterised in that the PVD layer contains nitrides and/or carbides of chromium, titanium, aluminium and/or tungsten, which are deposited alternately or simultaneously.

4. Method according to any one of the claims 1 to 3,
characterised in that the PVD layer has a hardness of from 800 to 4000 HV0.1.

5. Method according to any one of the preceding claims, characterised in that the DLC layer contains at least one, preferably all of the following layers: an adhesive layer of chromium and/or titanium having a layer thickness of 1.0 μm or less, at least one metal-containing intermediate layer of type a-C:H:Me, where Me=tungsten, titanium and/or chromium, or of type a-C:H:X, where X=silicon, germanium, fluorine, boron, oxygen and/or nitrogen, having a layer thickness of from 0.1 μm to 5 μm, and a metal-free top layer of type a-C:H having a layer thickness of from 0.1 μm to 5 μm.

6. Method according to claim 5,
characterised in that the metal-containing DLC layer contains nanocrystalline metal or metal carbide depositions, such as, for example, WC, CrC, SiC, GeC and/or TiC.

7. Method according to any one of the preceding claims, characterised in that the hardness of the DLC layer is from 2000 to 5000 HV0.002.

8. Piston ring having a coating which is formed at least partially on the inner face and has at least one PVD and/or DLC layer which has preferably been applied by means of PA-CVD, glow discharge and/or HIPIMS.
